(19) United States
(12) Patent Application Publication
(10) Pub. No.: US 2012/0320307 A1
(43) Pub. Date: Dec. 20, 2012

(54) ACTIVE MATRIX SUBSTRATE, GLASS SUBSTRATE, LIQUID CRYSTAL PANEL AND LIQUID CRYSTAL DISPLAY DEVICE

(75) Inventors: Hiroshi Aichi, Osaka (JP); Tetsuya Yamauchi, Osaka (JP); Norimasa Iwai, Osaka (JP); Yasuo Mizokoshi, Osaka (JP)

(73) Assignee: SHARP KABUSHIKI KAISHA, Osaka (JP)

(21) Appl. No.: 13/578,963

(22) PCT Filed: Nov. 12, 2010
(86) PCT No.: PCT/JP2010/070230

§ 371 Date: Aug. 29, 2012

(30) Foreign Application Priority Data
Feb. 18, 2010 (JP) 2010-033319

(51) Int. Cl. H01L 27/15; G02F 1/13357; G02F 1/1335

(52) U.S. Cl. 349/61; 349/110; 257/72; 257/E27.121

(57) ABSTRACT

Each pixel 105 includes a display part 111 for displaying an image and a sensor 112 for detecting light. The sensors 112 of the pixels 105 that are systematically pre-selected from a plurality of pixels 105 are provided with a photodiode 115 and a light-shielding film 116 in a manner such that the light-shielding film 116 is positioned below the photodiode 115 so as to overlap the photodiode 115 when viewed from the direction perpendicular to the active matrix substrate, and wiring lines 117 and bus lines 118 that electrically connect all light-shielding films 116 to each other are provided so as to avoid the display parts 111. This makes it possible to provide an active matrix substrate, a glass substrate, a liquid crystal panel, and a liquid crystal display device that can reduce the occurrence of damage due to electrostatic discharge when they are equipped with a light-receiving element and a light-shielding film to achieve optical sensor function.

### TECHNICAL FIELD

The present invention relates to an active matrix substrate equipped with optical sensors, a glass substrate, a liquid crystal panel, and a liquid crystal display device, and more specifically to a technique for reducing the occurrence of damage from electrostatic discharge in the vicinity of the optical sensors.

### BACKGROUND ART

In the past, a semiconductor device that functions as an optical sensor has been proposed (see Patent Document 1, for example). Such a semiconductor device is provided with a photodiode as a light-receiving element that conducts photoelectric conversion, and is built into electronic devices such as mobile telephones, display devices, and digital cameras. Such electronic devices use the semiconductor device to detect the surrounding light, thereby adjusting the brightness of a display panel, the exposure settings of a camera, and the like, for example.

However, with such a semiconductor device, there was a problem that the electrodes or semiconductor elements in the part where the photodiode is formed were damaged or the reliability of the semiconductor element was reduced due to a discharge of static electricity (electrostatic discharge) that occurred during manufacturing or use. In order to deal with this, in the semiconductor device disclosed in Patent Document 1, a dummy pattern that is susceptible to electrostatic discharge is provided as a measure to deal with electrostatic discharge occurring in the part where the photodiode is formed, thereby preventing the occurrence of damage from electrostatic discharge in main device parts.

The semiconductor device disclosed in Patent Document 1 is provided with a photodiode; an amplifier circuit; an electrode to be connected to the high potential side and an electrode to be connected to the low potential side, which are connected to a power source; and a dummy pattern (a dummy electrode formed of a conductive film). The semiconductor device has a configuration in which the dummy pattern is provided in the same layer as and adjacent to the electrode to be connected to the high potential side and the electrode to be connected to the low potential side, and has a greater area than those electrodes. Also, the dummy pattern is not electrically connected to the photodiode or the amplifier circuit, so that the electric potential thereof is floating. According to this configuration, there is a higher probability that the dummy pattern will sustain damage from an electrostatic discharge compared to the electrode to be connected to the high potential side and the electrode to be connected to the low potential side, and even if an electrostatic discharge occurs on the dummy pattern, damage from the electrostatic discharge in other components can be prevented. Also, by electrically connecting the dummy pattern to a substrate such as a printed circuit board, any electric charge that accumulates in the dummy pattern can be discharged to the substrate.

In recent years, a liquid crystal display device having an optical sensor function has been developed. Such a liquid crystal display device is provided with a liquid crystal panel equipped with optical sensors, and functions as a touch panel or a scanner by detecting changes in light levels when the screen is touched. In this liquid crystal panel, a photodiode is formed in each pixel on the active matrix substrate as an optical sensor.

However, since a metallic dummy pattern is formed in the same layer as the electrode to be connected to the high potential side and the electrode to be connected to the low potential side in the semiconductor device disclosed in Patent Document 1, a liquid crystal display device provided with such a semiconductor device is unsuited to applications such as touch panels as described above having the configuration in which photodiodes are formed within the pixels. In touch panels and the like, it is necessary to prevent light, which directly enters the photodiodes from a backlight, from becoming noise.

An optical sensor-type liquid crystal display device that can be applied to touch panels and the like is disclosed in Patent Document 2, for example. In the liquid crystal display device disclosed in Patent Document 2, a light-shielding film that shields light so that the light from the backlight does not directly enter the photodiode is provided in the layer below the semiconductor layer, which serves as the photodiode, in the active matrix substrate of the liquid crystal panel. The light-shielding film is provided for each photodiode, and the electric potential of the light-shielding film is floating.

### RELATED ART DOCUMENTS

### Patent Documents

Patent Document 1: Japanese Patent Application Laid-Open Publication, “Japanese Patent Application Laid-Open Publication No. 2008-182214 (Published on Aug. 7, 2008)”
Patent Document 2: Japanese Patent Application Laid-Open Publication, “Japanese Patent Application Laid-Open Publication No. 2009-237286 (Published on Oct. 15, 2009)”

### SUMMARY OF THE INVENTION

### Problems to be Solved by the Invention

However, the optical sensor-type liquid crystal display device disclosed in Patent Document 2 has the problem that during the manufacturing process of the liquid crystal panel damage from an electrostatic discharge occurs when transitioning between steps. This has resulted in poor reliability and a decrease in panel yield.

In consideration of the problem described above, the present invention aims to provide an active matrix substrate, a glass substrate, a liquid crystal panel, and a liquid crystal display device capable of reducing the occurrence of damage from an electrostatic discharge in a configuration in which the pixels are provided with light-receiving elements and light-shielding films.

### Means for Solving the Problems

In order to solve the problem mentioned above, an active matrix substrate of the present invention includes: an active area in which a plurality of pixels are arranged in a matrix; display parts and sensor parts provided in the respective pixels, the display parts being provided for displaying an image, the sensor parts being provided for detecting light; and light-receiving elements and first light-shielding films provided in the sensor parts of respective pixels that are systematically pre-selected from the plurality of pixels, wherein the first light-shielding films are formed in a lower layer than the light-receiving elements so as to overlap the light-receiving elements when viewed from a direction perpendicular to the active matrix substrate, and wherein the active matrix substrate further includes wiring that is provided so as to avoid the display parts and that electrically connects all of the first light-shielding films to each other.

In the past, there was a problem that during the manufacturing process of a liquid crystal panel having a configuration in which pixels are provided with light-receiving elements and light-shielding films, damage due to an electrostatic discharge occurred when transitioning between steps. Through diligent study, the inventors of the present invention discovered that the cause was that during the ion implantation step of forming the semiconductor layer of the light-receiving element, the glass substrate became electrified, and when transferring the glass substrate, peeling electrification occurred in the pin position of the transfer robot. Based on analysis, it was confirmed that the semiconductor layer and the gate oxide film over the light-shielding film were damaged by electrostatic discharge. The light-shielding film is provided for each semiconductor layer, and the electric potential of the light-shielding film is floating. From this, it was concluded that the electrostatic discharge occurred between light-shielding films.

In contrast, with the above configuration, because all of the first light-shielding films have the same electric potential, the electrostatic discharge that previously occurred between light-shielding films can be eliminated. Therefore, the occurrence of damage from an electrostatic discharge can be reduced.

In order to solve the above problem, a glass substrate of the present invention has a plurality of the above-mentioned active matrix substrates arranged in a matrix thereon with a cutting margin surrounding the respective active matrix substrates, wherein the above-mentioned wiring lines of the respective active matrix substrates are led out to the cutting margin, and wherein the cutting margin is provided with an inter-substrate wiring line that electrically connects all wiring lines of the respective active matrix substrates to each other.

According to the configuration, by being provided with the inter-substrate wiring line, all light-shielding film layers within the glass substrate have the same electric potential. Therefore, even if the quantity of electricity stored on the glass substrate becomes larger, it is possible to prevent the occurrence of electrostatic discharge between the light-shielding films of each active matrix substrate in the glass substrate. Therefore, the occurrence of damage from an electrostatic discharge can be reduced.

In order to solve the above problem, a liquid crystal panel of the present invention is provided with the above-mentioned active matrix substrate.

According to the configuration, by providing the above active matrix substrate, the occurrence of damage due to electrostatic discharge can be reduced, and a liquid crystal panel with excellent reliability can be provided.

In order to solve the above problem, a liquid crystal display device of the present invention is provided with the above-mentioned liquid crystal panel and a light source device.

According to the above configuration, by providing the above liquid crystal panel, the occurrence of damage from an electrostatic discharge can be reduced, and a liquid crystal display device with excellent reliability can be provided.

### Effects of the Invention

As described above, the active matrix substrate of the present invention is provided with wiring lines that are disposed so as to avoid the display parts and that electrically connect all of the first light-shielding films to each other, thereby giving all of the first light-shielding films the same electric potential, which can eliminate occurrences of electrostatic discharge that had previously occurred between light-shielding films. Therefore, the effect of reducing the occurrence of damage due to electrostatic discharge is attained.

The glass substrate of the present invention has a configuration in which the wiring lines of each active matrix substrate is led out into the cutting margin, and the cutting margin is provided with the inter-substrate wiring line that electrically connects all of the wiring lines of the respective active matrix substrates. This allows all of the light-shielding film layers within the glass substrate to have the same electric potential, and therefore, even if the quantity of electricity stored in the glass substrate becomes larger, electrostatic discharge between the light-shielding films of the respective active matrix substrates on the glass substrate can be prevented. Therefore, the effect of reducing the occurrence of damage due to an electrostatic discharge is attained.

The liquid crystal panel of the present invention has a configuration in which the above-mentioned active matrix substrate is provided. Also, the liquid crystal display device of the present invention has a configuration in which the liquid crystal panel and a light source device are provided. Therefore, both can reduce the occurrence of damage due to electrostatic discharge, and the effect of providing a liquid crystal panel and a liquid crystal display device with excellent reliability is attained.

### BRIEF DESCRIPTION OF THE DRAWINGS

FIG. 1 is a schematic plan view that shows one embodiment of a liquid crystal panel of the present invention.

FIG. 2 is a magnified plan view of a region a of FIG. 1 that shows the configuration of pixels in an active area of the above-mentioned liquid crystal panel.

FIG. 3 is a cross-sectional view that shows the cross-sectional configuration of a sensor part of one pixel in an active matrix substrate of the liquid crystal panel.

FIG. 4 is a plan view that shows the configuration of the layer in which light-shielding films are formed in the active matrix substrate of the liquid crystal panel.

FIGS. 5(a) to 5(d) are cross-sectional views that show the manufacturing steps of the sensor part up to the step in which an amorphous silicon film, which becomes a photodiode, is formed.

FIG. 6 is a plan view that shows one embodiment of a glass substrate of the present invention.

FIG. 7 is a magnified view of the active matrix substrate in the above glass substrate.

FIG. 8 is a plan view that shows another embodiment of the liquid crystal panel of the present invention, and shows the configuration of the layer in which the light-shielding films are formed in the active matrix substrate.

### DETAILED DESCRIPTION OF EMBODIMENTS

### Embodiment 1

One embodiment of the present invention is described below with reference to figures.

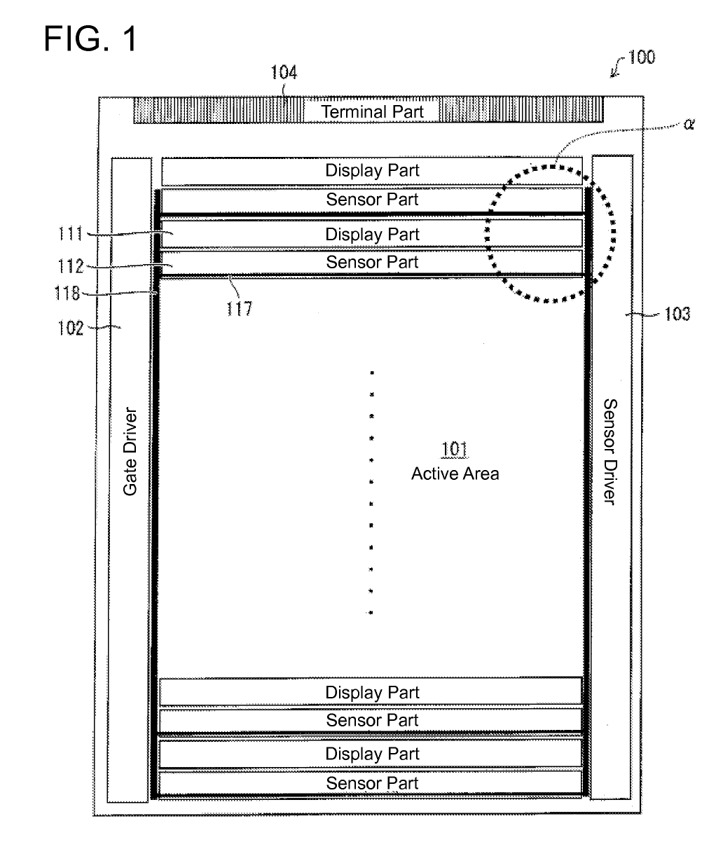

In the description below, the up to down direction in FIG. 1 is referred to as the vertical direction, and the left to right direction in FIG. 1 is referred to as the horizontal direction. Additionally, the surface view of FIG. 1, in other words the view from the perpendicular direction to the liquid crystal panel (active matrix substrate), is referred to as the plan view.

(Overall Configuration)

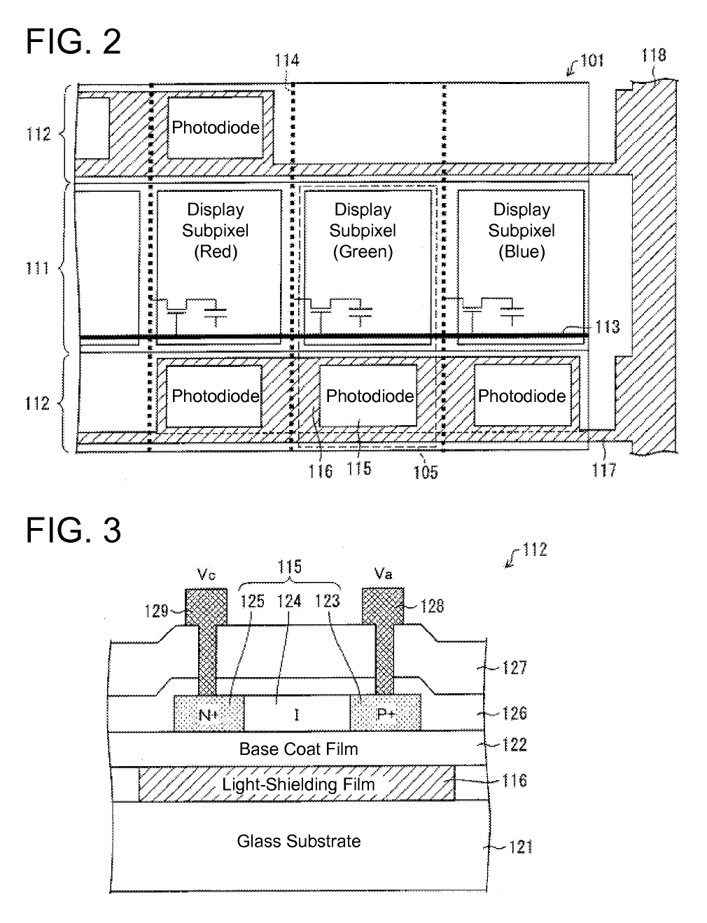

FIG. 1 is a schematic plan view that shows one example of a configuration of a liquid crystal panel 100 according to the present embodiment. FIG. 2 is a magnified plan view of a region α of FIG. 1, which shows the configuration of pixels 105 in an active area 101.

As shown in FIG. 1, the liquid crystal panel 100 is provided with the active area 101, a gate driver 102 (driver), a sensor driver 103 (driver), and a terminal part 104. An active matrix driving method is used for the liquid crystal panel 100.

The active area 101 is a region in which pixels 105 are arranged in a matrix of n rows and k columns (n and k being integers of at least 2). All pixels 105 each have the same configuration, and as shown in FIG. 2, each pixel includes a display part 111 that displays images and a sensor part 112 that detects light. The display part 111 is arranged in the upper side of the pixel 105 in a plan view. The sensor part 112 is arranged in the lower side of the pixel 105 in a plan view. As a result, when viewing the entire active area 101, as shown in FIG. 1, the display parts 111 and the sensor parts 112, which extend in the horizontal direction, are arranged in an alternating stripe-pattern.

The display part 111 and the sensor part 112 of the pixel 105 may be arranged in the opposite order or left and right, and do not need to be arranged on the same side in all pixels. A layout in which even-numbered rows have the sensor part 112 on the upper side and odd-numbered rows have the sensor part 112 on the lower side is also possible, for example.

The display part 111 is provided with a pixel electrode, a common electrode (opposite electrode), and a pixel circuit that at least contains a thin film transistor (TFT), for example, but may also have other elements as long as it has a general active matrix drive type configuration. It is possible to provide the pixel circuit, which applies a voltage to the pixel electrode thereof in accordance with control from the gate driver 102, with an auxiliary capacitance, a memory circuit, and the like, for example. The sensor part 112 is provided with a photodiode 115, which is a light-receiving element, a light-shielding film 116 (first light-shielding film), and the like. The sensor part 112 may also include a capacitance, a read-out TFT, and the like (none shown in figures) as appropriate, for example.

In the active area 101, the display parts 111 of three pixels 105 that are arranged so as to be adjacent to one another in the horizontal direction are respectively allocated to R (red), G (green), and B (blue) to constitute one display pixel.

Also, prescribed pixels 105 are provided with one photodiode 115 each. Specifically, the pixels 105 are provided with photodiodes 115 in a systematic pattern in the horizontal direction such that three pixels 105 having photodiodes and one pixel 105 not having a photodiode are alternately arranged. The pattern is not limited to the above-mentioned example, and two pixels having the photodiodes and two pixels not having the photodiodes may be alternately arranged, or the photodiodes 115 may be provided for all pixels 105. Any arrangement patterns may be employed as long as the photodiodes 115 are provided in the sensor parts 112 of the respective pixels 105 that are systematically pre-selected from the plurality of pixels 105. The number of pixels within one sensor pixel can be determined based on the sensor resolution. Also, the photosensitivity can be increased by providing one photodiode 115 for each pixel 105, and by using a few pixels as one sensor pixel unit.

In the active area 101, gate lines 113 are provided so as to extend in the horizontal direction while source lines 114 are provided so as to extend in the vertical direction, corresponding to the display parts 111 of the respective pixels 105. The gate line 113 is provided within the display part 111. Also, wiring lines 117 (first wiring lines, third wiring lines) are provided within the sensor parts 112 of the respective rows so as to extend in the horizontal direction. Bus lines 118 (wiring lines, second wiring lines, fourth wiring lines) is provided so as to extend in the vertical direction between the active area 101 and the gate driver 102, and between the active area 101 and the sensor driver 103.

FIGS. 1 and 2 show the sensor part 112 as being relatively large in order to clearly show the sensor part 112, but the actual sensor part 112 is narrower in the vertical direction than the display part 111 to the degree that the sensor part 112 does not interfere with the image display of the liquid crystal panel 100.

The gate driver 102 generates a scanning signal for selecting pixels 105 to be driven, and outputs the scanning signal to the corresponding gate line 113. The sensor driver 103 drives the optical sensor function by applying a voltage from a power source to each photodiode 115. The gate driver 102 and the sensor driver 103 are arranged to face one another in the horizontal direction so as to sandwich the active area 101.

The terminal part 104 is provided with a plurality of terminals that can be connected to the outside of the liquid crystal panel 100. The terminal part 104 is provided on the periphery of the active area 101 and on one edge in the vertical direction of the liquid crystal panel 100. Respective terminals are electrically connected to the source lines 114 of the active area 101, the gate driver 102, and the sensor driver 103.

The liquid crystal panel 100 has a configuration in which a liquid crystal layer is sandwiched between two substrates that face one another, although this is not shown in the figures. One of the substrates has a common electrode and the like formed therein. The other substrate (hereinafter referred to as an active matrix substrate) has the gate lines 113, the source lines 114, the pixel circuits, the pixel electrodes, the terminal part 104, and the like formed therein. Also, the gate driver 102 and the sensor driver 103 are built monolithically into the active matrix substrate.

The liquid crystal panel 100 having the above configuration is provided in the liquid crystal display device as a display part having an optical sensor function. The so-called optical sensor-type liquid crystal display device having an optical sensor function is provided with other conventional general configurations, in addition to the liquid crystal panel 100. For example, the liquid crystal display device is provided with display drivers such as a source driver that generates data signals to drive the pixels 105 and that outputs the data signals to the corresponding source lines 114, a Vcom driver that supplies a common electric potential to the common electrode, and a timing generator that generates a clock signal for instructing a timing, a backlight (light source device) that illuminates the liquid crystal panel 100 from the rear, and the like (none shown in the figures).

The above liquid crystal display device has a configuration in which display drivers other than the gate driver 102 and the sensor driver 103 are electrically connected to the liquid crystal panel 100 via the terminal part 104, but the configuration is not limited to such, and it is also possible to monolithically build the display drivers into the active matrix substrate of the liquid crystal panel 100 in the same manner as the gate driver 102 and the sensor driver 103. Conversely, the gate driver 102 and the sensor driver 103 may be provided outside of the liquid crystal panel 100.

The above liquid crystal display device is built into various electronic devices such as personal computers as a display device providing functions such as a touch panel function in which input operations can be made on the basis of the position of an object touching the surface of the panel or a scanner function that scans images, in addition to the normal image display function.

(Configuration of Sensor Part)

Next, the configuration of the sensor part 112 of the pixel 105, and in particular, the configuration of the area in the vicinity of where the photodiode 115 is formed will be described.

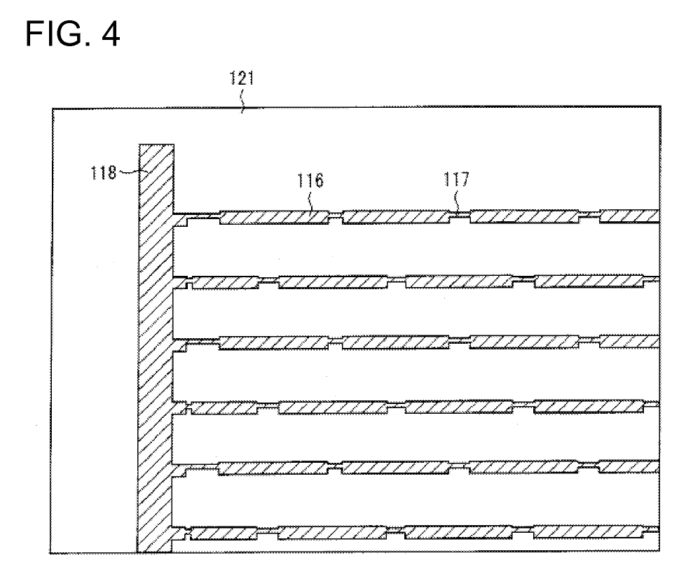

FIG. 3 is a cross-sectional view that shows the cross-sectional configuration of the sensor part 112 of one pixel 105 in the active matrix substrate. FIG. 4 is a plan view that shows the configuration of the layer where the light-shielding films 116 are formed. FIG. 4 omits members other than the light-shielding films 116, the wiring lines 117, and the bus line 118 so as to clarify the layout of the light-shielding films 116.

As shown in FIGS. 3 and 4, in the active matrix substrate, the sensor part 112 has a configuration in which the light-shielding films 116, the wiring lines 117, a base coat film 122, the photodiode 115, a gate oxide film 126, an interlayer insulating film 127, an anode (Va) 128, and a cathode (Vc) 129 are formed on a glass substrate 121.

The glass substrate 121 is a transparent substrate with glass as the main material. The light-shielding film 116 is formed on the glass substrate 121. The light-shielding film 116 has a light-shielding function that prevents the photodiode 115 from being constantly in an excited state due to light from the backlight being incident thereon. The light-shielding film 116 has a rectangular shape in a plan view, and is placed so as to overlap the photodiode 115. The light-shielding film 116 may be place so as to overlap a plurality of adjacent photodiodes 115, or may be provided for each photodiode 115 as long as the light-shielding film 116 overlaps the photodiode 115. The light-shielding film 116 is made of a metal such as molybdenum (Mo), for example.

The wiring lines 117 are formed on the glass substrate 121. In other words, the wiring lines 117 are formed in the same layer as the light-shielding film 116. As shown in FIG. 4, the wiring lines 117 are provided so as to extend in the horizontal direction, and are connected to the respective light-shielding films 116 arranged in the horizontal direction, thereby establishing the electrical connection with the respective light-shielding films 116. The wiring lines 117 are desirably made of the same material as the light-shielding film 116, which makes it possible to form the wiring lines 117 integrally with the light-shielding films 116.

As shown in FIG. 4, a bus line 118 is formed on the glass substrate 121 in the same layer as the light-shielding films 116 and the wiring lines 117. The bus line 118 is provided so as to extend in the vertical direction, and is connected to the respective wiring lines 117, thereby establishing the electrical connection with the respective wiring lines 117. This way, by the wiring lines 117 and the bus line 118, the potential of all light-shielding films 116 is maintained at the same level. The bus line 118 is desirably made of the same material as the light-shielding films 116 and the wiring lines 117, which makes it possible to form the bus line 118, the light-shielding films 116, and the wiring lines 117 integrally.

Over the glass substrate 121 where the light-shielding films 116 and the wiring lines 117 are formed, a base coat film 122 is formed. The base coat film 122 serves as a base film for the photodiode 115 located in the layer above.

The photodiode 115 is formed on the base coat film 122. The photodiode 115 is a PIN photodiode, and is made of a semiconductor layer in which an intrinsic semiconductor region (I layer) 124 is sandwiched between a p-type semiconductor region (P layer) 123 and an n-type semiconductor region (N layer) 125. The semiconductor layer is arranged so as to overlap the light-shielding film 116 in a plan view.

On the base coat film 122 upon which the photodiode 115 is formed, the gate oxide film 126 and the interlayer insulating film 127 are layered in this order. The anode 128 and the cathode 129 are formed on the interlayer insulating film 127. The anode 128 and the cathode 129 are electrically connected respectively to the p-type semiconductor region 123 and the n-type semiconductor region 125 of the photodiode 115 via contact holes formed through the gate oxide film 126 and the interlayer insulating film 127. Also, the anode 128 and the cathode 129 are electrically connected to the sensor driver 103.

The sensor part 112, which has the above configuration, can be made into a sensor such as a visible light sensor or an infrared (IR) sensor by making the semiconductor layer that forms the photodiode 115 of a material corresponding to the wavelength of light to be detected. When making the sensor part into an infrared sensor, a light pen or the like that emits infrared light may be used as the input tool.

In the above configuration, the base coat film 122, the gate oxide film 126, and the interlayer insulating film 127 are continuously formed in the sensor parts 112 of the pixels 105 of each row. Also, the sensor part 112 is formed on the glass substrate 121 together with the display part 111, and therefore, the base coat film 122, the gate oxide film 126, and the interlayer insulating film 127 may be shared with the display part 111.

(Manufacturing Method for Sensor Part)

Next, a manufacturing method for the sensor part 112 of the pixel 105 will be described. Here, the manufacturing method for the infrared sensor and the visible light sensor will be described as examples.

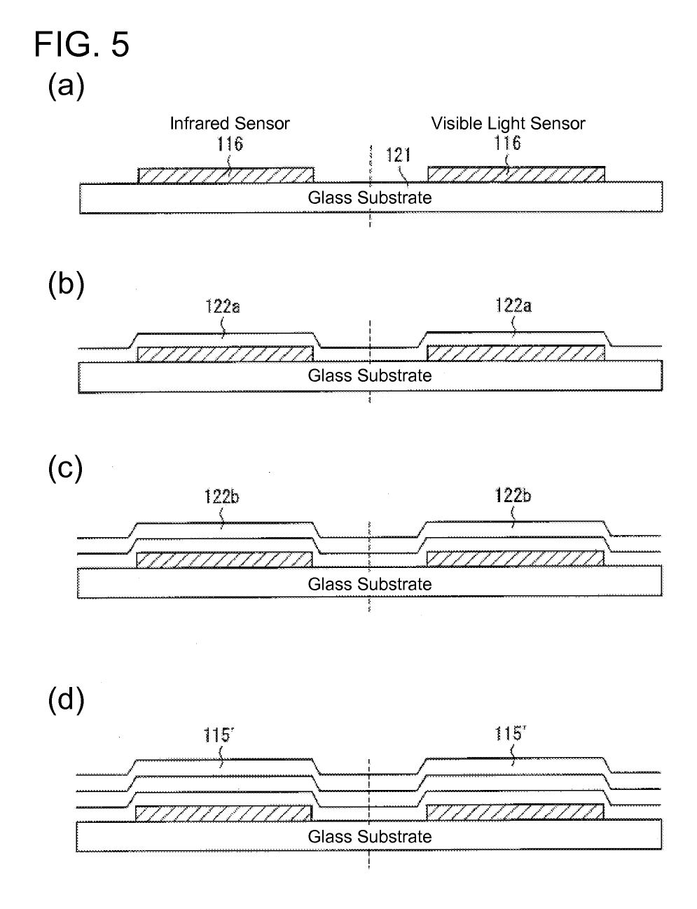

FIGS. 5(a) to 5(d) are cross-sectional views that show the manufacturing steps for the sensor part 112 up to the step in which an amorphous silicon (a-Si) film 115′ that is made into the photodiode 115 is formed. The left hand side of the figures shows the infrared sensor while the right hand side shows the visible light sensor.

<Step of Forming Light-Shielding Film 116>

First, as shown in FIG. 5(a), light-shielding films 116 are formed in prescribed positions on the glass substrate 121. Specifically, the light-shielding films 116 are formed in positions overlapping the semiconductor layers to be formed in a later step, by depositing a metal film on the glass substrate 121 by sputtering, and by patterning the film through a method such as photography. In this step, the wiring lines 117 and the bus lines 118 are also formed on the glass substrate 121 by using the same method as the method of forming the light-shielding films 116. The light-shielding films 116, the wiring lines 117, and the bus lines 118 can all be formed integrally and simultaneously when the same material is used for all.

<Step of Forming First Base Coat Film 122a>

As shown in FIG. 5(b), a first base coat film 122a is formed on the glass substrate 121 where the light-shielding films 116, the wiring lines 117, and the bus line 118 have been formed. Specifically, an even coating of the first base coat film 122a is formed on the glass substrate 121 upon which the light-shielding films 116, the wiring lines 117, and the bus line 118 have been formed. The first base coat film 122a is formed so as to block contamination from the glass substrate 121, and is made of a silicon nitride film, for example.

<Step of Forming Second Base Coat Film 122b>

As shown in FIG. 5(c), a second base coat film 122b is formed on the first base coat film 122a. Specifically, an even coating of the second base coat film 122b is formed on the first base coat film 122a. The second base coat film 122b is formed so as to maintain the stability of the interface with the semiconductor layer, which is to be formed in the next step, and is made of a silicon oxide film, for example.

<Step of Forming Semiconductor Layer>

The semiconductor layer to be the photodiode 115 is formed on the second base coat film 122b. Specifically, as shown in FIG. 5(d), an even layer of an amorphous silicon (a-SI) film 115′ is formed on the second base coat film 122b. Although no further steps are shown in the figures, the amorphous silicon layer is polysiliconized through a method such as laser annealing, and by thereafter conducting patterning and the like, the semiconductor layer is formed.

After the semiconductor layer has been formed in the manner described above, the gate oxide film 126, the interlayer insulating film 127, and the like are formed in this order by using a conventional manufacturing method, which completes the sensor part 112 as shown in FIG. 3. The light-shielding films 116 located in a lower layer than the semiconductor layers (photodiode 115) are all at the same electric potential as a result of the wiring lines 117 and the bus lines 118 formed in the same layer as the light-shielding films 116.

As described above, the liquid crystal panel 100 of the present embodiment, specifically the active matrix substrate, has a configuration in which the wiring lines 117 and the bus lines 118 are laid out to avoid the display parts 111 and to electrically connect all light-shielding films 116 to each other.

In the past, there was a problem in which during the manufacturing steps of a liquid crystal panel having the configuration of the pixel being provided with a light-receiving element and a light-shielding film, damage from an electrostatic discharge occurred when transitioning between steps. The inventors of the present invention have, through diligent study, discovered that the cause is that during the ion implantation step of forming the semiconductor layer of the light-receiving element, the glass substrate became electrified, and when transferring the glass substrate, peeling electrification occurred in the pin location of the transfer robot. Based on analysis, it was confirmed that the semiconductor layer and the gate oxide film over the light-shielding film were damaged due to electrostatic discharge. The light-shielding film is provided for each semiconductor layer, and the electric potential of the light-shielding films is floating. From this, it was concluded that the electrostatic discharge occurred between light-shielding films.

With the above configuration in the present embodiment, all of the light-shielding films 116 have the same electric potential, thus eliminating the occurrence of electrostatic discharge between light-shielding films, which had occurred previously. Therefore, it is possible to reduce the occurrence of damage from electrostatic discharge.

Also, as shown in FIG. 2, each light-shielding film 116 is placed and shaped so as to overlap the photodiode 115, in other words the whole semiconductor layer, in a plan view. The light-shielding film 116 is arranged such that the photodiode 115 is positioned within the area of the light-shielding film 116 in a plan view (so as to encircle the semiconductor layer), which allows the light-shielding film 116 to electrically shield the semiconductor layer, and can therefore protect the semiconductor layer from electrostatic discharge more reliably.

The plan view shape of the light-shielding film 116 is not limited to a rectangular shape. The wiring lines 117 and the bus line 118 need to be arranged such that the light-shielding films 116 are traversable, and it is also possible to arrange them in the opposite manner to that shown in FIG. 1, for example. In this case, the wiring line 117 can be provided for each column so as to extend in the vertical direction, and the bus lines 118 can be provided between the active area 101 and the terminal part 104, and in the periphery of the opposite side of the active area 101 so as to extend in the horizontal direction. The wiring lines 117 need to be arranged so as to avoid the display parts 111 depending on how the display parts 111 and the sensor parts 112 within the pixels 105 are arranged with respect to one another. Also, the bus lines 118 need to be arranged in the periphery of the active area 101 so as to avoid the display parts 111.

Also, a PIN photodiode was used for the photodiode 115 in the above active matrix substrate, but it is also possible to use a photodiode of other types such as a PN photodiode. Furthermore, the light-receiving element (sensor element) is not limited to the photodiode 115, and a capacitance or the like may also be used, for example.

### Embodiment 2

In Embodiment 1, the effect in which the occurrence of electrostatic discharge was reduced by having the light-shielding films 116 in the liquid crystal panel 100 at the same electric potential was described. However, if the quantity of electricity stored in the glass substrate becomes larger, it is possible for an electrostatic discharge to occur between light-shielding films between the plurality of panels arranged on a large sheet of glass before the glass is cut into individual pieces. Therefore, a configuration in which the occurrence of electrostatic discharge is reduced in a pre-cut liquid crystal panel 100 is desirable.

Another embodiment of the present invention will be described below with reference to figures. Configurations other than that described in the present embodiment are the same as those of Embodiment 1. Also, for ease of description, the same reference characters are given to members having the same functions as those of the members shown in the figures of Embodiment 1, and descriptions thereof are omitted.

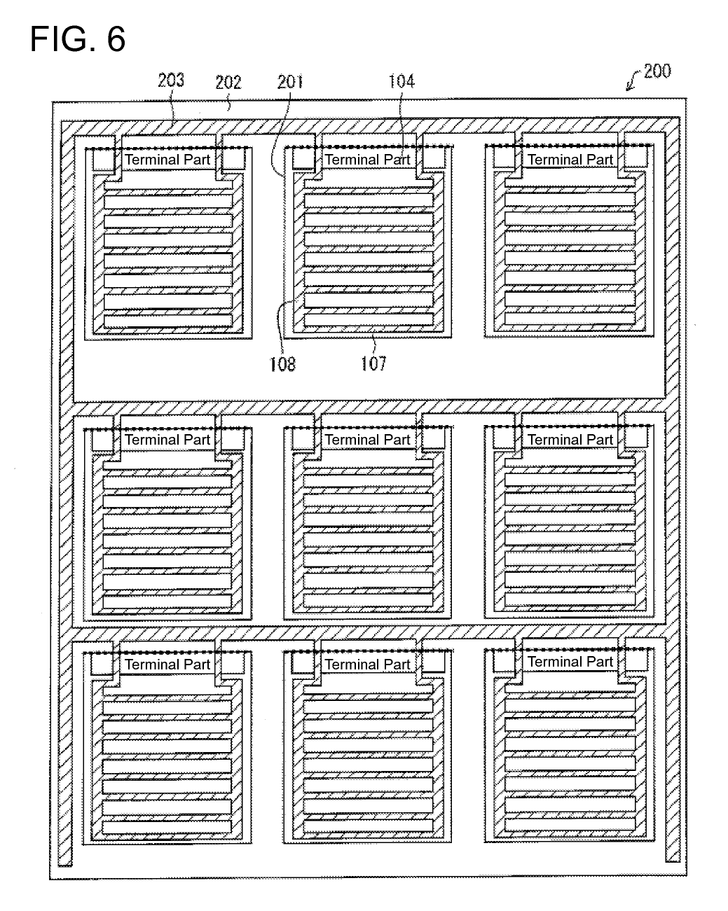

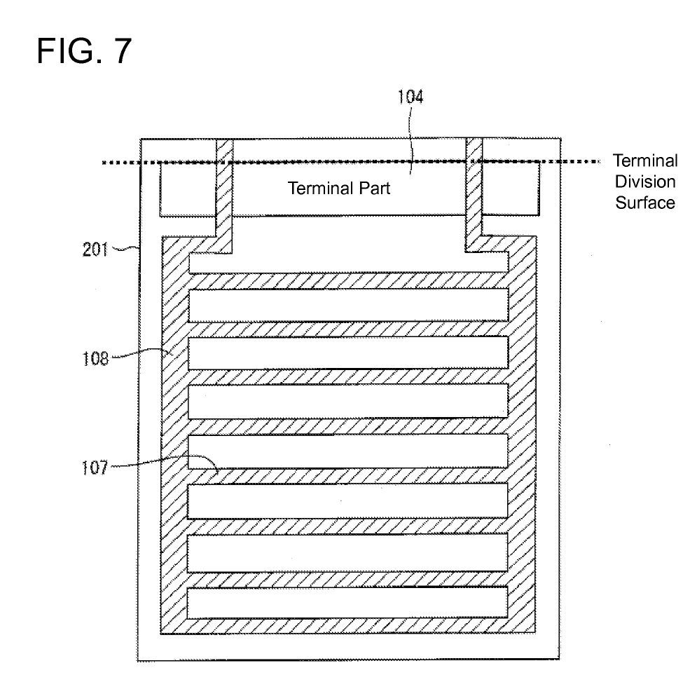

FIG. 6 is a plan view that shows an example of the configuration of a glass substrate 200 of the present embodiment. In FIG. 6, in order to clarify the layout of the wiring lines 117, the bus lines 118, and a wiring line 203, other members are omitted as appropriate. FIG. 7 is a magnified view of an active matrix substrate 201 in the glass substrate 200 of FIG. 6.

As shown in FIG. 6, the glass substrate 200 has a configuration in which the active matrix substrates 201 are arranged in a matrix by forming electric circuits such as TFTs on one large sheet of mother glass. Here, a total of nine active matrix substrates 201 of 3 rows×3 columns are arranged on the glass substrate, but this is just one example. The active matrix substrate 201 has the same configuration as that of the active matrix substrate of Embodiment 1 except that the gate driver 102 and the sensor driver 103 are not provided. The glass substrate 200 is eventually cut so that each individual active matrix substrate 201 is cut out. A cutting margin 202 surrounds the active matrix substrates 201 for this purpose.

Also, the glass substrate 200 is provided with the wiring line 203 (inter-substrate wiring). The wiring line 203 is connected to the bus lines 118 of each active matrix substrate 210, thereby establishing the electrical connection with the bus lines 118. The wiring line 203 is in the cutting margin 202, and is arranged in the same layer as the bus lines 118. Meanwhile, in each active matrix substrate 201, the bus lines 118 pass through the terminal part 104, and are led to outside of the active matrix substrate 201 (to within the cutting margin 202 region).

By being provided with the wiring line 203, the potential of all light-shielding film layers within the glass substrate 200 is maintained at the same level. Therefore, even if the quantity of electricity stored with the glass substrate become larger, it is possible to prevent the occurrence of electrostatic discharge between the light-shielding films of the respective active matrix substrates 201 in the glass substrate 200. Therefore, it is possible to reduce the occurrence of damage due to electrostatic discharge. Also, it is possible to increase the tolerance thereof to electrostatic discharge to greater than that of Embodiment 1.

When dividing the glass substrate 200 into individual panels, the cutting margin 202 in which the wiring line 203 is provided is cut off and discarded. Although the active matrix substrate 201 described above was only provided with an active area 101, it may also be provided with drivers in the periphery.

### Embodiment 3

Another embodiment of the present invention will be described below with reference to figures. Configurations other than that described for the present embodiment are the same as those of Embodiments 1 and 2. Also, for ease of description, the same reference characters are given to members that have the same functions as those shown in figures for Embodiments 1 and 2, and descriptions thereof are omitted.

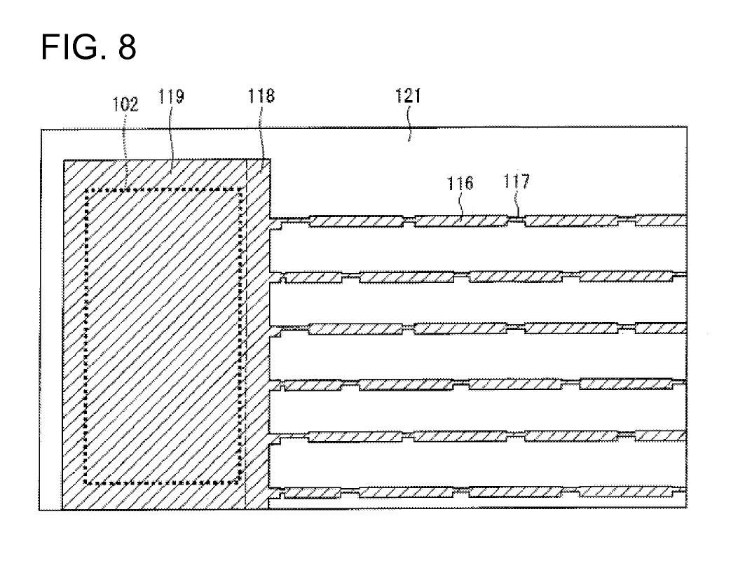

FIG. 8 shows an example of a configuration of a liquid crystal panel of the present embodiment, and is a plan view that shows the configuration of the layer in which light-shielding films 116 in the active matrix substrate are formed. In FIG. 4, members other than the light-shielding films 116, the wiring lines 117, and the bus line 118 are omitted to clarify the layout of the light-shielding films 116.

The liquid crystal panel of the present embodiment differs from the liquid crystal panel 100 of Embodiment 1 only in the configuration of the layer in which the light-shielding films 116 are formed. In other words, as shown in FIG. 8, in the layer in which the light-shielding films 116 are formed in the active matrix substrate of the liquid crystal panel of the present embodiment, a light-shielding film 119 (second light-shielding film) is provided below TFTs in the gate driver 102. By providing the light-shielding film 119 below the TFTs, increases in the OFF current due to light from the backlight can be reduced.

The light-shielding film 119 is connected to the bus line 118, thereby establishing the electrical connection with the bus line 118. As a result, occurrences of electrostatic discharge due to the placement of the light-shielding film 119 can be reduced, and with respect to the TFTs of the drivers provided in the periphery of the panel, the semiconductor layers thereof can be protected.

In FIG. 8, the light-shielding film 119 is provided in the entire region of the gate driver 102, but because the driver parts such as the gate driver 102 do not affect the display characteristics of the pixels 105, any layout of the light-shielding film 119 is possible as long as the semiconductor layers of the TFTs of the driver part are included therein. When providing light-shielding films 119 individually, for example, wiring lines for connecting the light-shielding films 119 to the bus line 118 may be provided as appropriate. Also, although not shown in figures, if the sensor driver 103 also is constituted of TFTs, it is preferable that the light-shielding film provided below such TFTs be electrically connected to the bus line 118 in the same manner.

When the TFT has a top-gate structure, it is not possible to create the above-mentioned configuration with the light-shielding film until gate wiring is formed, and therefore, it is effective to form the light-shielding film 119 and the wiring in the first step of creating the TFT, as wiring to prevent electrostatic discharge.

The electric potential of the light-shielding film 119 changes depending on the operating state of the TFT, and therefore, it is preferable to set the potential of the light-shielding film 119 to an appropriate fixed potential. The voltage to the light-shielding film 119 can be provided from the source line 114 by forming a contact between the light-shielding film 119 and the source line 114, for example.

The present invention is not limited to the embodiments described, and various modifications can be made without departing from the scope of the claims. Embodiments that are attained by appropriately combining the techniques disclosed in the different embodiments are also included in the technical scope of the present invention.

The active matrix substrate of the present invention includes: an active area in which a plurality of pixels are arranged in a matrix; display parts and sensor parts provided in the respective pixels, the display parts being provided for displaying an image, the sensor parts being provided for detecting light; light-receiving elements and first light-shielding films provided in the sensor parts of respective pixels that are systematically pre-selected from the plurality of pixels, wherein the first light-shielding films are formed in a lower layer than the light-receiving elements so as to respectively overlap the light-receiving elements when viewed from a direction perpendicular to the active matrix substrate, and wherein the active matrix substrate further includes wiring that is laid out to avoid the display parts and that electrically connects all of the first light-shielding films to each other.

In order to achieve an effective wiring arrangement, in the active matrix substrate of the present invention, the wiring preferably includes first wiring lines that are disposed in the active area in a same layer as the first light-shielding films, the respective first wiring line connecting the first light-shielding films provided in respective pixels in each row to each other; and a second wiring line that is disposed in a periphery of the active area in the same layer as the first light-shielding films, the second wiring line connecting the first wiring lines to each other.

Alternatively, in the active matrix substrate of the present invention, the wiring includes: third wiring lines that are disposed in the active area in a same layer as the first light-shielding films, the respective third wiring line connecting the first light-shielding films provided in respective pixels in each column to each other; and a fourth wiring line that is disposed in a periphery of the active area in the same layer as the first light-shielding films, the fourth wiring line connecting the third wiring lines to each other.

In the active matrix substrate of the present invention, the first light-shielding films are preferably arranged such that the light-receiving elements are respectively located inside the first light-shielding films when viewed from the direction perpendicular to the active matrix substrate. As a result, the first light-shielding films are used as electrical shields, making it possible to protect the semiconductor layer from electrostatic discharge more reliably.

It is preferable that the active matrix substrate of the present invention further include: a driver that drives the plurality of pixels, the driver being formed monolithically in the periphery of the active area; at least one thin film transistor included in the driver; and a second light-shielding film formed in the driver. It is also preferable that the second light-shielding film be formed in a lower layer than the thin film transistor so as to overlap the thin film transistor when viewed from the direction perpendicular to the active matrix substrate, and be electrically connected to the wiring.

According to the above configuration, by arranging the second light-shielding film below the thin film transistor, increases in the OFF current due to light from the backlight can be reduced. Also, because the second light-shielding film is electrically connected to the wiring, occurrences of electrostatic discharge due to the placement of the second light-shielding film can be reduced, and the semiconductor layers of the thin film transistors of the driver formed in the periphery of the active area can also be protected.

### INDUSTRIAL APPLICABILITY

The present invention can not only be suitably used in fields related to optical sensor type active matrix substrates provided with light-shielding films, but also can be suitably used in fields related to manufacturing methods for active matrix substrates. Further, the present invention can be used in a wide range of fields such as liquid crystal panels equipped with active matrix substrates, liquid crystal display devices provided with liquid crystal panels, electronic devices provided with liquid crystal display devices, and the manufacturing methods thereof.

### DESCRIPTION OF REFERENCE CHARACTERS

100 liquid crystal panel
101 active area
102 gate driver (driver)
103 sensor driver (driver)
104 terminal part
105 pixel
111 display part
112 sensor part
115 photodiode (light-receiving element)
116 light-shielding film (first light-shielding film)
117 wiring (first wiring lines, third wiring lines)
118 bus line (wiring lines, second wiring lines, fourth wiring lines)
119 light-shielding film (second light-shielding film)
200 glass substrate
201 active matrix substrate
202 cutting margin
203 wiring line (inter-substrate wiring)

1. An active matrix substrate, comprising:
an active area in which a plurality of pixels are arranged in a matrix;
display parts and sensor parts provided in said respective pixels, the display parts being provided for displaying an image, the sensor parts being provided for detecting light; and
light-receiving elements and first light-shielding films provided in said sensor parts of respective pixels that are systematically pre-selected from the plurality of pixels,
wherein the first light-shielding films are formed in a lower layer than the light-receiving elements so as to respectively overlap the light-receiving elements when viewed from a direction perpendicular to the active matrix substrate, and
wherein the active matrix substrate further comprises wiring that is laid out to avoid the display parts and that electrically connects all of the first light-shielding films to each other.

2. The active matrix substrate according to claim 1, wherein the wiring includes:
first wiring lines that are disposed in the active area in a same layer as the first light-shielding films, the respective first wiring line connecting the first light-shielding films provided in respective pixels in each row to each other; and
a second wiring line that is disposed in a periphery of the active area in the same layer as the first light-shielding films, the second wiring line connecting said first wiring lines to each other.

3. The active matrix substrate according to claim 1, wherein the wiring includes:
third wiring lines that are disposed in the active area in a same layer as the first light-shielding films, the respective third wiring line connecting the first light-shielding films provided in respective pixels in each column to each other; and
a fourth wiring line that is disposed in a periphery of the active area in the same layer as the first light-shielding films, the fourth wiring line connecting said third wiring lines to each other.

4. The active matrix substrate according to claim 1, wherein the first light-shielding films are arranged such that the light-receiving elements are respectively located inside the first light-shielding films when viewed from the direction perpendicular to the active matrix substrate.

5. The active matrix substrate according to claim 1, further comprising:
a driver that drives the plurality of pixels, the driver being formed monolithically in the periphery of the active area;
at least one thin film transistor included in the driver; and
a second light-shielding film formed in the driver,
wherein the second light-shielding film is formed in a lower layer than the thin film transistor so as to overlap the thin film transistor when viewed from the direction perpendicular to the active matrix substrate, and is electrically connected to said wiring.

6. A glass substrate on which a plurality of active matrix substrates are arranged in a matrix with a cutting margin surrounding the respective active matrix substrates, wherein each of the active matrix substrates is the active matrix substrate according to claim 1,
wherein said wiring of the respective active matrix substrates is led out to the cutting margin, and
wherein the cutting margin is provided with an inter-substrate wiring line that electrically connects all the wiring of the respective active matrix substrates to each other.

7. A liquid crystal panel, comprising the active matrix substrate according to claim 1.

8. A liquid crystal display device, comprising the liquid crystal panel according to claim 7 and a light source device.
